(19) United States
(12) Patent Application Publication
(10) Pub. No.: US 2011/0079847 A1
(43) Pub. Date: Apr. 7, 2011

(54) Semiconductor Device

(76) Inventors: Mika Ebihara, Chiba-shi (JP); Tomomitsu Risaki, Chiba-shi (JP)

(21) Appl. No.: 12/928,272

(22) Filed: Dec. 7, 2010

Related U.S. Application Data
(62) Division of application No. 12/380,430, filed on Feb. 27, 2009.

(30) Foreign Application Priority Data
Feb. 8, 2006 (JP) 2006-031210

(51) Int. Cl. H01L 29/78

(52) U.S. Cl. 257/335; 257/E29.255

(57) ABSTRACT

Provided is a semiconductor device capable of easily setting a holding voltage with a low trigger voltage by locally forming a P-type diffusion layer between N-type source and drain diffusion layers of an NMOS transistor having a conventional drain structure used as an electrostatic protective element of the semiconductor device.

### BACKGROUND OF THE INVENTION

1. Field of the Invention

The present invention relates to a semiconductor device, and more particularly, to a semiconductor device used for preventing damage due to a static electricity to a CMOS semiconductor device.

2. Description of the Related Art

Up to now, in a CMOS semiconductor device, as an electrostatic discharge (hereinafter, referred to as “ESD”) protective element, an NMOS transistor having a conventional drain structure in which a gate electrode is held to a substrate potential as shown in FIG. 3 is used in many cases. The operation principle of this transistor is that surface breakdown of the transistor, which takes place in the voltage range between the maximum operating voltage of the CMOS semiconductor device and a voltage which does not cause breakdown in a standard NMOS transistor, triggers current flow between the drain 103b and the P-type substrate 101 to increase the potential of the substrate 101, causing a forward-bias voltage between the source 103a working as an emitter, and the P-type substrate working as a base, which turns on the NPN bipolar action to discharge the applied huge electricity. In addition, adjustment of the length L, which is a length of a channel of the NMOS transistor, enables an easy setting of the holding voltage at the time of the NPN bipolar action, equal to or higher than the maximum operating voltage of the semiconductor device. After completion of discharging of the whole electric charge, the semiconductor device can return to a steady state. A structure of an N+ layer provided on a drain side, in which heat is most likely to generate at the breakdown of the NMOS transistor, is an important factor for determining a current resistance (heat resistance) of the ESD protective element. Phosphorus is generally used as an impurity for the N+ diffusion layer with which structure for diffusing generated heat, that is, a deeper and uniform profile, can be obtained (See JP 2001-144191 A and JP 2002-524878 A).

However, with the advancement in miniaturization of a semiconductor device and downsizing of an electronic device using the same, reductions in a voltage of the CMOS semiconductor device and in a thickness of a gate oxide film have been promoted, there arises a problem in that, in a conventional electrostatic protection circuit using an NMOS transistor having a conventional drain structure, voltage reaches the gate oxide film breakdown before the surface breakdown occurs, or the CMOS semiconductor device damages due to a static electricity before the electrostatic protective circuit operates.

### SUMMARY OF THE INVENTION

It is an object of the present invention to provide an electrostatic protective element capable of arbitrarily setting an operating voltage (trigger voltage) and a holding voltage at a low level, which has not been achieved in a conventional electrostatic protective circuit using an NMOS transistor having a conventional drain structure, with a small occupation area at low cost.

In order to attain the above-mentioned object, a semiconductor device according to the present invention adopts the following means.

(1) There is provided a semiconductor device, including: a P-type well region formed on a P-type semiconductor substrate; a field oxide film formed on the P-type well region; a gate electrode formed on the P-type well region through a gate oxide film; N-type source and drain regions surrounded by the field oxide film and the gate electrode; a P-type region which is formed to contact with the source region locally between the N-type source and drain regions and has a concentration higher than that of the P-type well region; an interlayer dielectric film for electrically insulating the gate electrode, the N-type source and drain regions, and the wiring formed on an upper layer thereof; and a contact hole for electrically connecting the wiring, the gate electrode, and the N-type source and drain regions to one another.
(2) There is provided a semiconductor device in which the P-type region is formed on an entire area between the N-type source and drain regions.
(3) There is provided a semiconductor device in which a concentration of an impurity introduced in the P-type region formed between the N-type source and drain regions is set to 1E16 to 1E20 atoms/cm³.
(4) There is provided a semiconductor device in which an impurity introduced in the N-type source and drain regions is phosphorus.
(5) There is provided a semiconductor device in which the N-type source and drain regions has a double diffusion structure in which impurities of phosphorus and arsenic are introduced.

According to the present invention, a P-type impurity is introduced in an electrostatic protective circuit using an NMOS transistor having a conventional drain structure, thereby making it possible to obtain an element capable of easily setting a holding. voltage with a trigger voltage at a low level, which has not been achieved in a conventional electrostatic protective circuit using an NMOS transistor having a conventional drain structure. As a result, it is possible to achieve an ESD protective circuit capable of protecting the CMOS transistor, in which the voltage is reduced, from the ESD, thereby obtaining a significant effect in a plurality of ICs.

### BRIEF DESCRIPTION OF THE DRAWINGS

In the accompanying drawings:

FIG. 1 is a schematic sectional diagram of an ESD protective element of a conventional NMOS transistor showing a semiconductor device according to a first embodiment of the present invention;

FIG. 2 is a schematic sectional diagram of the ESD protective element of the conventional NMOS transistor showing the semiconductor device according to a second embodiment of the present invention; and

FIG. 3 is a sectional diagram of an ESD protective element of a conventional phosphorus-diffused conventional NMOS off-transistor.

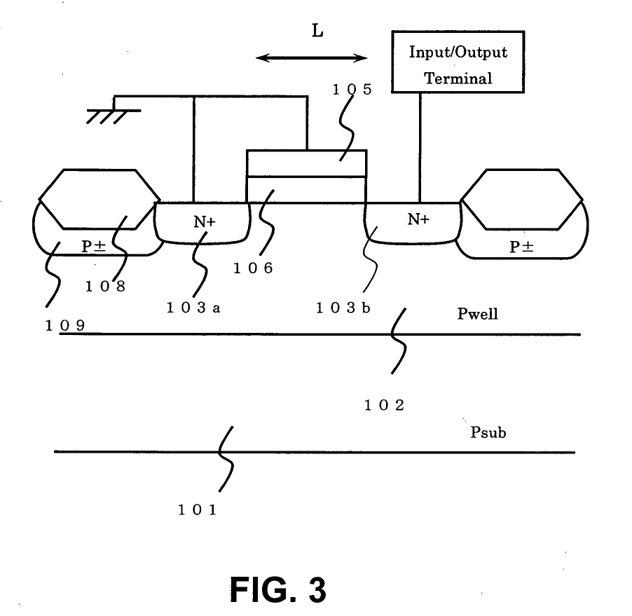

### DETAILED DESCRIPTION OF THE PREFERRED EMBODIMENTS

Hereinafter, preferred embodiments of the present invention will be described with reference to the attached drawings.

### First Embodiment

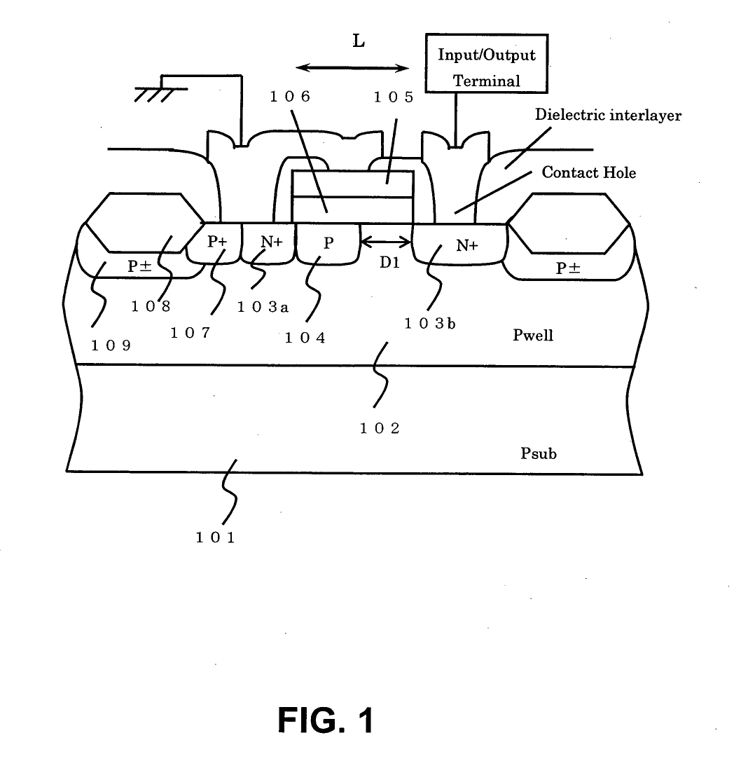

FIG. 1 is a schematic sectional diagram of an NMOS transistor having a conventional drain structure of a semiconductor device according to a first embodiment of the present invention.

The NMOS transistor includes a P-type well region 102 formed on a P-type silicon semiconductor substrate 101, a gate oxide film 106 and a polysilicon gate electrode 105 which are formed on the P-type well region 102, a P-type diffusion layer 104 having a high concentration which is formed to contact with the source region locally between an N-type source diffusion layer 103a and an N-type drain diffusion layer 103b, which are formed on a surface of a silicon substrate at both ends of the gate electrode and have a high concentration, and a P-type diffusion layer 107 which is provided so as to take a potential of the P-type well region 102, and has a high concentration. N-type drain diffusion layer 103b is connected to an input/output terminal through wiring, and the N-type source diffusion layer 103a, the P-type diffusion layer 107 which is provided to take the potential of the P-type well region 102, and the polysilicon gate electrode 105 are connected to Vss wiring which is a reference potential. In addition, there is formed an interlayer dielectric film in which contact holes provided so as to electrically connect the wiring, the gate electrode, and the N-type source and drain diffusion layers are accumulated. A field oxide film 108 and a channel stop region 109 are formed between elements for isolation of the elements. Note that the semiconductor substrate is not necessarily used. Alternatively, an N-type silicon semiconductor substrate may be used to form the NMOS transistor.

When a positive electric charge enters the input/output terminal, an N+P diode of the P-type diffusion layer 104 formed between the N-type drain diffusion layer 103b and the N-type source diffusion layer 103a breaks down, which causes a trigger voltage. Then, a current is caused to flow in the P-type well region 102, and a bipolar operation of an NPN transistor, which includes an N-type drain diffusion layer, a P-type well layer, and an N-type source diffusion layer, is turned on, thereby making it possible to discharge the electric charge quickly. By changing a concentration of each of the N-type drain diffusion layer and the P-type diffusion layer, it is possible to easily set the trigger voltage to a gate oxide film breakdown voltage or less at a maximum rating or more. In order to form the P-type diffusion layer, BF₂ ions or boron ions are implanted at a dose amount of 1×10¹² to 1×10¹⁶ atoms/cm². When the mount is converted to a concentration, a concentration of about 1×10¹⁶ to 1×10²⁰ atoms/cm³ is obtained. Further, the P-type diffusion layer is formed between the N-type source diffusion layer and the N-type drain diffusion layer, thereby making it possible to suppress punch-through and reducing a length L.

Further, as shown in FIG. 1, a distance (D1) between the N-type drain diffusion layer 103b and the P-type diffusion layer 104 formed immediately below the gate electrode is changed, thereby making it possible to easily setting the holding voltage at the time of the bipolar operation of the NPN transistor to an arbitrary value. In addition, by changing the concentration of the P-type diffusion layer, it is possible to easily set the holding voltage to an arbitrary value.

Due to the N-type drain diffusion layer in which heat is most likely to generate at the breakdown of the N+P diode, phosphorus by which a deep and uniform concentration profile is obtained is used to diffuse the heat generation. As a result, it is possible to improve the heat resistance of the ESD protective element. Further, it is possible to employ a double diffusion layer in which a phosphorus and an arsenic are used as impurities to be introduced in the N-type source and drain diffusion layers when the N-type source and drain diffusion layers are formed. Through implantation of the arsenic, it is possible to easily reduce a breakdown pressure of the N+P diode.

Further, the gate electrode is wired to the reference potential Vss, thereby making it possible to suppress a leak current. Note that the gate electrode is not necessarily provided.

### Second Embodiment

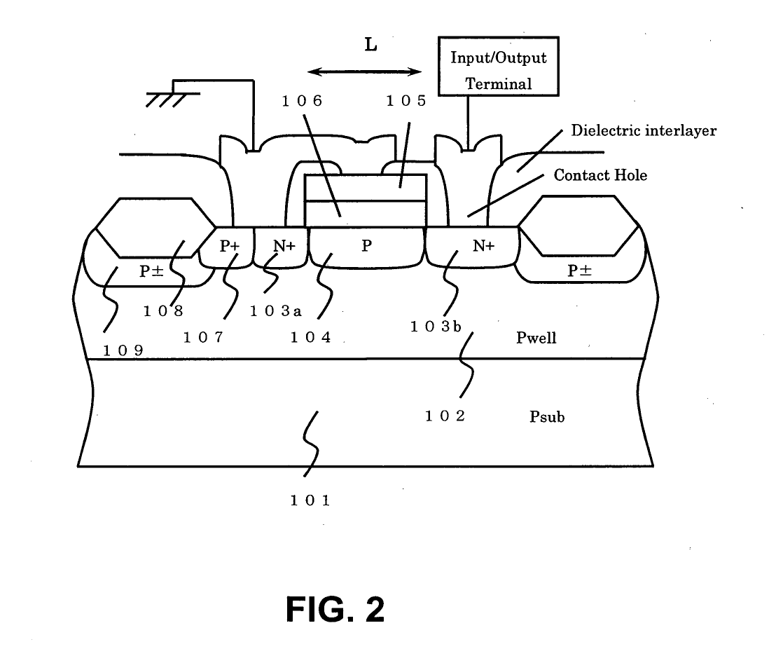

FIG. 2 is a schematic sectional diagram of an NMOS transistor having a conventional drain structure of a semiconductor device according to a second embodiment of the, present invention.

As shown in FIG. 2, a P-type diffusion layer may be formed on an entire area provided immediately below a gate between N-type source and drain diffusion layers.

1.-6. (canceled)

7. A semiconductor device comprising:
a semiconductor substrate;
a P-type well region disposed in the semiconductor substrate;
a field oxide film disposed on the P-type well region and surrounding an active element region;
a gate electrode disposed on a gate oxide film disposed on the active element region;
N-type source and drain regions surrounded by the field oxide film and the gate electrode; and
a P-type region disposed in contact with the N-type source region but not in contact with the N-type drain region for lowering a breakdown voltage of the semiconductor device.

8. A semiconductor device according to claim 7; wherein the P-type region has a concentration higher than that of the P-type well region.

9. A semiconductor device according to claim 7; further comprising a dielectric interlayer disposed over the gate electrode; and a plurality of contact holes formed in the dielectric interlayer for receiving wirings to electrically connect together the gate electrode and the N-type source and drain regions.

10. A semiconductor device according to claim 8; wherein the semiconductor substrate has one of an N-type and a P-type conductivity.

11. A semiconductor device according to claim 8; wherein the P-type region contains an impurity having a concentration in the range of 1×10¹⁶ to 1×10²⁰ atoms/cm³.

12. A semiconductor device according to claim 8; wherein each of the N-type source and drain regions contains an impurity of phosphorus.

13. A semiconductor device according to claim 8; wherein the N-type source and drain regions have a double diffusion structure in which impurities of phosphorus and arsenic are introduced.
